(19) United States
(12) Patent Application Publication
(10) Pub. No.: US 2014/0333335 A1
(43) Pub. Date: Nov. 13, 2014

(54) PROBE

(71) Applicant: Gunsei KIMOTO, Tokyo (JP)

(72) Inventor: Gunsei KIMOTO, Tokyo (JP)

(21) Appl. No.: 13/890,800

(22) Filed: May 9, 2013

(51) Int. Cl. G01R 1/067

(52) U.S. Cl. CPC G01R 1/067
USPC 324/754.03

(57) ABSTRACT

A probe includes a first deforming portion which includes a linkage mechanism formed by a vertical probe and a plurality of horizontal beams extending in a direction perpendicular to vertical direction, one ends of the horizontal beams being connected to a fixed end and the other ends being connected to the vertical probe, wherein: a vertical portion of the vertical probe extending from the horizontal beams forms a second deforming portion including a horizontal beam portion extending toward the fixed end from an intermediate part of the vertical portion; and scrubbing of the vertical probe in whole operation of an overdrive is strictly controlled by causing bending moment to act on the horizontal beam portion of the second deforming portion, simultaneously with the overdrive applying in a direction in which bending moment applied to the vertical probe of the first deforming portion is offset.

### BACKGROUND OF THE INVENTION

1. Field of the Invention

The present invention relates to a contact element (a probe) for inspecting circuits of a plurality of chips formed on a wafer in a manufacturing process of electronic devices, such as LSIs. More particularly, the present invention relates to a probe structure mounted on a probe card for use in the inspection of circuits formed on a wafer. The probes are made to contact with electrode pads arranged on the chip as a wafer for a collective measurement of electrical conductivity of the chip.

2. Description of Prior Art

As the semiconductor technology advances, electronic devices are becoming more and more densely integrated and a circuit wiring area is increasing in each semiconductor wafer chip formed on a semiconductor wafer. With this, pads on each semiconductor chip are increasing in number, whereby pad areas are becoming smaller and pad pitch widths are becoming narrower.

A probe card has been used for the inspection of the semiconductor chips on the semiconductor wafer. The probe card is equipped with a plurality of needle probes each having a portion which is elastically deformable by external force. The probe card is disposed between a pad of a to-be-inspected semiconductor chip and an inspection unit.

The more dense arrangement of the pads and the narrowed pitch widths of the pads cause a problem that the probe structure which is made to contact with the pad of the semiconductor chip for the electrical conduction should be small and high density in accordance with the dense pad arrangements.

The reduced pad areas cause a problem that a scrubbing amount should be controlled strictly. In particular, in the electronic devices provided with an aluminum alloy film pads, such as a memory LSI and a logic LSI, in which an oxide film existing on a pad surface must be destroyed in a horizontal rubbing (i.e., scrubbing) operation of a probe tip in order to establish electrical conduction, the scrubbing amount must be controlled strictly to prevent not only removal of the probe tip out of the pad during the scrubbing operation but also occurrence of insufficient wire bonding due to an increased area of scrubbing marks with respect to the pad areas.

A typical probe structure is a needle-shaped probe having a cantilever structure. In a related art cantilever structure, there is a tradeoff between a vertical displacement amount of the tip (i.e., an overdrive amount) and a horizontal displacement amount of the tip (i.e., a scrubbing amount).

This means that a relatively large overdrive amount is needed in order to secure proper pressure force that does not damage the pads and simultaneously to absorb vertical dimensional variation to reliably provide a plurality of pads with pressure force greater than a certain threshold. Such a relatively large overdrive amount requires an increased length of the cantilever, which is an obstacle to the dense arrangement of the cantilevers.

With a compact cantilever having reduced beam length, in contrast, there is also a problem that a large overdrive amount cannot be provided and it is therefore difficult to reliably provide a plurality of pads with pressure force greater than a certain threshold simultaneously.

Pads of an LSI for a liquid crystal display (LCD) driver which are expected to have a narrower pad pitch width (20 micrometers or less) are formed by, for example, a gold plating on which an oxide film is less easily formed. If a probe designed for scrubbing as described above is used in these pads of the LCD driver LSI, the gold plating which is a pad material is removed. As a result, there arises a problem that the probe tip must be cleaned periodically and there is a possibility that adhesion of metal debris causes, for example, damage to the probe or insufficient electric conduction.

In view of the aforementioned circumstances, a technical requirement for the probe is to simultaneously achieve following matters:

(1) a high density probe array applicable to pad arrangements with narrow pitch widths;
(2) a great overdrive amount; and
(3) strict control of a probe behavior near a contact portion of the probe having a scrubbing function. The present inventors have proposed structures as proposed in Japanese Patent Disclosure Nos. 2008-122356 and 2009-036774 described below.

The invention disclosed in the Japanese Patent Disclosure No. 2008-122356 which employs a probe structure with a parallel spring structure instead of a related art cantilever structure provides a relatively large overdrive amount and, at the same time, enables strict control of a horizontal behavior of the probe structure near a contact portion of the pad and the probe. In addition, a rotating deforming portion connected to a tip of the parallel spring structure enables strict control of the scrubbing operation.

The invention disclosed in the Japanese Patent Disclosure No. 2009-036774 in which a distance between at least a pair of opposing parallel beams among horizontal beams in a parallel spring structure varies continuously or discontinuously along a horizontal direction enables further strict control in a horizontal behavior.

If, however, a related art probe designed for scrubbing is used in the LSIs that require no scrubbing operation, such as the LCD driver LSIs, the gold plating which is a pad material is removed by the scrubbing operation. As a result, there arises a problem that periodic cleaning is required and insufficient electric conduction is caused.

If a related art probe designed for scrubbing is used in a related art aluminum electrode pad which requires a scrubbing operation, an oxide film on the surface of the electrode pad is excessively removed and, therefore, the electrode pad material may be destroyed. As a result, there arises a problem that periodic cleaning is required and wire bonding becomes insufficient.

The present invention has been made in order to solve these problems and a first object thereof is to provide a probe which eliminates a horizontal scrubbing operation at a probe tip as much as possible and establishes electrical conduction by the minimum contact force. A second object is to provide a probe which includes a parallel spring deforming structure provided mainly for a vertical operation and a horizontally-oriented small deforming structure which is provided at an extended portion of a vertical probe section, and has functions to correct a horizontal displacement produced by a behavior of the parallel spring deforming structure and keep an amount of the horizontal displacement close to zero as much as possible.

### SUMMARY OF THE INVENTION

A first invention of the present invention is a probe which includes a linkage mechanism formed by a vertically extending vertical probe and a pair of horizontal beams which extend in a direction crossing to the vertical direction and have a linear or curved configuration, one ends of the horizontal beams being connected to a fixed end and the other ends being connected to the vertical probe, and a distance between the pair of opposing horizontal beams varies continuously or discontinuously along a horizontal direction, wherein: the distance between the horizontal beams is maximum at the fixed end and is minimum at the other ends near the vertical probe. By this construction, horizontal displacement (i.e., a scrubbing amount) of a tip of the vertical probe becomes very small in the whole area of the overdrive without providing the second deforming portion.

A second invention of the present invention is a probe in which initial angle (the angle at a moment before the probe acts) formed between a horizontal beam of the pair of horizontal beams disposed on a side of the tip of the vertical probe (on the side of electrode pad to-be-inspected) and horizontal line is set to 0 degree. By this construction, horizontal displacement (i.e., a scrubbing amount) of a tip of the vertical probe becomes very small in the whole area of the overdrive without providing the second deforming portion.

A third invention of the present invention is characterized in that the displacement amount of the linkage mechanism is calculated according to the formula of matrix analyzing method shown below, wherein the displacement of the tip of the vertical probe in the direction of X-axis among the displacement of the tip of the vertical probe in the matrix is nearly 0;

$$\begin{matrix}{p}_{1} = \vert \begin{matrix}{F}_{x 1} \\ {F}_{y 1} \\ {m}_{1}\end{matrix} \vert & {p}_{2} = \vert \begin{matrix}{F}_{x 2} \\ {F}_{y 2} \\ {m}_{2}\end{matrix} \vert \\ {d}_{1} = \vert \begin{matrix}{δ}_{x 1} \\ {δ}_{y 1} \\ {θ}_{1}\end{matrix} \vert & {d}_{2} = \vert \begin{matrix}{δ}_{x 2} \\ {δ}_{y 2} \\ {θ}_{2}\end{matrix} \vert\end{matrix} \} \\ \begin{matrix}{p}_{1} = {K}_{11} {d}_{1} + {K}_{12} {d}_{2} \\ {p}_{2} = {K}_{21} {d}_{1} + {K}_{22} {d}_{2}\end{matrix} \} \\ \begin{matrix}{K}_{11} = [ \begin{matrix}\frac{EA}{L} & 0 & 0 \\ 0 & \frac{12 EI}{{L}^{3}} & \frac{6 EI}{{L}^{2}} \\ 0 & \frac{6 EI}{{L}^{2}} & \frac{4 EI}{L}\end{matrix} ] & {K}_{12} = [ \begin{matrix}- \frac{EA}{L} & 0 & 0 \\ 0 & - \frac{12 EI}{{L}^{3}} & \frac{6 EI}{{L}^{2}} \\ 0 & - \frac{6 EI}{{L}^{2}} & \frac{2 EI}{L}\end{matrix} ] \\ {K}_{21} = [ \begin{matrix}- \frac{EA}{L} & 0 & 0 \\ 0 & - \frac{12 EI}{{L}^{3}} & - \frac{6 EI}{{L}^{2}} \\ 0 & \frac{6 EI}{{L}^{2}} & \frac{2 EI}{L}\end{matrix} ] & {K}_{22} = [ \begin{matrix}\frac{EA}{L} & 0 & 0 \\ 0 & \frac{12 EI}{{L}^{3}} & - \frac{6 EI}{{L}^{2}} \\ 0 & - \frac{6 EI}{{L}^{2}} & \frac{4 EI}{L}\end{matrix} ]\end{matrix} \}$$

wherein;
Fₓ: Load in the direction of X
F_{y}: Load in the direction of Y
δₓ: Displacement in the direction of X
δ_{y}: Displacement in the direction of Y
E: Young's modulus of the beam
I: Second section moment of the beam
A: Cross sectional of the beam
L: Length of the beam

According to the thus-structured probe of the present invention, a small deforming structure, which is the second deforming portion having functions to correct horizontal displacement accompanying horizontal displacement or rotational displacement caused by a behavior of the first deforming portion, and strictly control the horizontal displacement, i.e., a scrubbing amount, at a level as low as 2 micrometers or less, is formed at the tip of the first deforming portion. With this construction, no removal of the electrode pad material occurs by a related art scrubbing operation for the LSIs that require no scrubbing operation, like the LCD driver LSIs. Further, since a proper scrubbing amount is provided for the electrode pad that requires a related art scrubbing operation, an oxide film on the surface of the electrode pad is penetrated without causing any removal of the oxide film to establish electrical conduction. Accordingly, there is an advantageous effect that no periodic cleaning is necessary and thus cost for inspecting the LSI can be reduced.

Other features and advantages of the present invention will be described in more detail below with reference to the accompanying drawings.

### BRIEF DESCRIPTION OF THE DRAWINGS

FIG. 1 is an explanatory view of a basic structure of a probe according to a first embodiment of the present invention;

FIGS. 2 (a)-(d) are explanatory views of an operation of the probe structure according to the first embodiment of the present invention;

FIGS. 2(a′)-(c′) show probe structures having no second deforming portion at the same first deforming portion but having a vertically extended portion of the same vertical length as that of the second deforming portion shown in FIGS. 2(a)-(c);

FIGS. 3(a)-(d) are explanatory views of a probe structure and an operation thereof according to a second embodiment of the present invention;

FIGS. 3(a′)-(c′) show probe structures having no second deforming portion at the same first deforming portion but having a vertically extended portion of the same vertical length as that of the second deforming portion shown in FIGS. 3(a)-(c);

FIGS. 4a and 4b are explanatory views of a probe structure and an operation thereof according to a third embodiment of the present invention;

FIG. 5 is an explanatory view regarding a probing operation of the probe structure according to the third embodiment of the present invention;

FIG. 6 is an explanatory view of a shape of a probe tip according to a fourth embodiment of the present invention; and

FIGS. 7(a)-(c) are explanatory views of a probing operation according to a fifth embodiment of the present invention.

### DESCRIPTION OF THE PREFERRED EMBODIMENTS

### First Embodiment

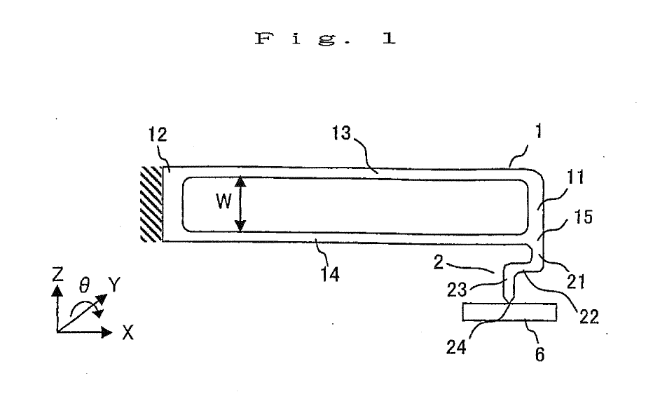

Referring now to the drawings, a first embodiment of the present invention will be described below. FIG. 1 is a schematic explanatory view of a probe structure related to the first embodiment of the present invention. FIG. 1 illustrates a vertical probe 11, a fixed end 12 and horizontal beams 13 and 14. The vertical probe 11, the fixed end 12 and the horizontal beams 13 and 14 constitute a substantially parallelogram spring using a linkage mechanism as a principle. This structure is called a first deforming portion 1.

A second deforming portion 2 is connected in series to an end of the vertical probe 11. The second deforming portion 2 includes a vertical portion 21, a horizontal beam portion 22 and a vertical portion 23. The vertical portion 21 extends vertically from a lower end 15 of the vertical probe 11 and has the length of L21. The horizontal beam portion 22 continues from the vertical portion 21 toward a fixed end 12 and has the length of L22. The vertical portion 23 continues vertically from the horizontal beam portion 22 and has the length of L23. Although the lengths of L21, L22 and L23 are illustrated as substantially L21≈L22≈L23 in FIG. 1, the lengths are not limited thereto.

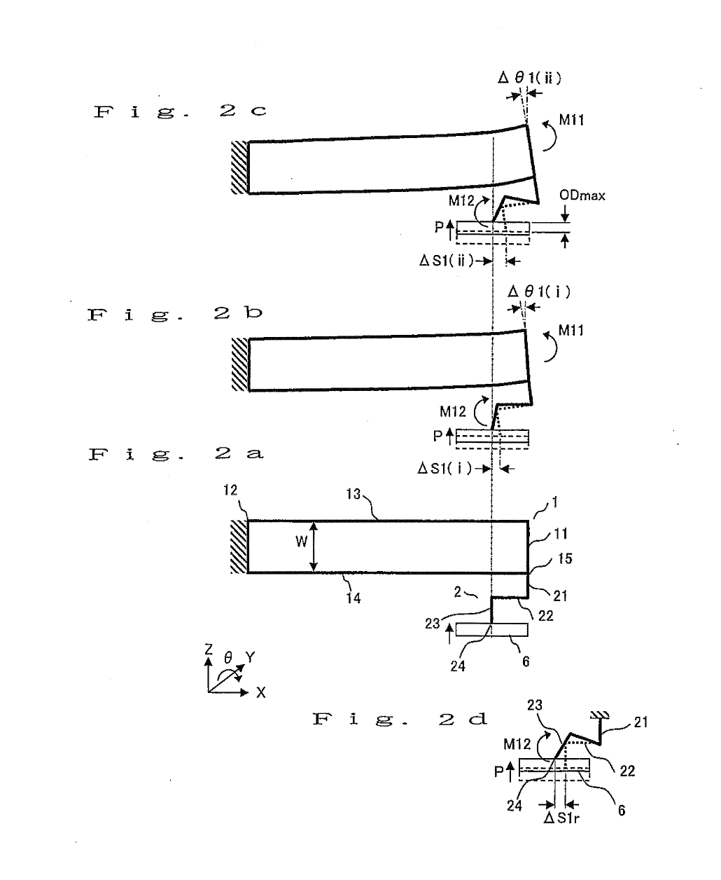

Next, an operation of the probe in the example of FIG. 1 will be described with reference to FIGS. 2A to 2D. In FIGS. 2A to 2D, the beam structure illustrated in FIG. 1 is illustrated in a simplified manner. FIGS. 2A to 2D illustrate the probe structure according to the present invention. The probe structure illustrated in FIGS. 2A′ to 2C′ has no second deforming portion at the same first deforming portion 1 but has a vertically extended portion 25 of the same vertical length as that of the second deforming portion 2. The following description will be given with the comparison of these structures.

In a related art cantilever structure which will be described later, bending deformation due to bending moment about an Y-axis of the horizontal beam is dominant with respect to load P in a +Z direction accompanying overdrive. In contrast to this, it is known in a parallelogram spring structure that the bending deformation is very small because shearing deformation of the two horizontal beams 13 and 14 is applied and thus the rotational displacement of the vertical probe 11 due to large displacement in the Z direction is very small. Accordingly, a parallelogram cantilever structure is suited for a behavior of the probe for which an overdrive amount in a sufficient amount to absorb variation in positions of the probe tips after a plurality of probes are assembled together.

The displacement amount is determined in accordance with, for example, the lengths L13 and L14 and the widths D13 and D14 of the horizontal beams 13 and 14, initial accuracy of the horizontal beam in the horizontal direction and a distance W between the horizontal beams as parameters.

With reference to FIGS. 2A to 2D, an operation of the first deforming portion 1 will be described first. The horizontal beams 13 and 14 of the probe are kept in substantially horizontal positions until the pad 6 undergoes a relative vertical movement (in the +Z direction) and contacts a vertical probe tip 24 (FIGS. 2A and 2A′).

Then, when the pad 6 starts contacting the vertical probe tip 24 and overdrive is applied to push the vertical probe tip 24 vertically upward in a certain fixed amount, the two parallel beams 13 and 14 undergo rotational displacement substantially parallel to each other due to the composition of the shear displacement and the very small bending moment M11 in the −θy direction and, accompanying this, the vertical probe 11 moves vertically and undergoes rotational displacement by a very small angle Δθ1(i) (FIG. 2B). At this time, in FIG. 2B′, the vertically extended portion 25 undergoes rotational displacement together with the vertical probe and, as a result, the tip 24 undergoes horizontal displacement in a +X direction by ΔS1′(i), i.e., performs the scrubbing operation.

When the vertical probe tip 24 is vertically pushed up to the maximum overdrive amount ODmax within the elastic limit of the parallel beams 13 and 14, the vertical probe 11 further undergoes vertical displacement and rotational displacement by an angle Δθ1(ii) (FIG. 2C). At this time, in FIG. 2C′, the vertically extended portion 25 undergoes rotational displacement together with the vertical probe and, as a result, the tip 24 undergoes horizontal displacement by ΔS1′(ii) in the +X direction.

The amount of rotational displacement Δθ1 can be arbitrarily set in accordance with the beam lengths L13 and L14, the beam widths D13 and D14, thickness of the metallic foil T, a distance between the beams W and a spring constant k of the material in the parallel spring as parameters.

An operation of the second deforming portion 2 will be described with reference to FIGS. 2A to 2D. The second deforming portion 2 can be considered as a very small cantilever with one end 15 of the vertical probe 11 as a fixed end and the horizontal beam portion 22 as a beam.

As illustrated in FIG. 2D, in a single operation with the end of the second deforming portion 2 as a fixing section, when the pad 6 starts contacting the vertical probe tip 24 and overdrive is applied, the beam sections 21, 22 and 23 undergo rotational displacement as illustrated by the solid line due to the act of bending moment M12 in a +θy direction. As a result, the vertical probe tip 24 is moved a very small distance ΔS1r in a horizontal direction. This horizontal distance ΔS1r is determined in accordance with the beam lengths L21, L22 and L23 and the beam widths D21, D22 and D23 as parameters.

Accompanying the rotational displacement of the vertical probe 11 at the first deforming portion 1, the second deforming portion 2 has already undergone rotational displacement by an angle of rotation Δθ1. Accordingly, the second deforming portion 2 as a whole undergoes the rotational displacement Δθ1 and, at the same time, the vertical probe tip 24 undergoes horizontal displacement in a −x direction relatively as a very small cantilever. Here, in an actually used probing operation range, since Δθ1 is very small, a horizontal displacement distance ΔS1r in FIG. 2D can be considered to be substantially the same as the relative horizontal displacement distance ΔS1 of the rotational displacement the second deforming portion 2 undergoes in FIGS. 2B and 2C.

Accordingly, by causing the bending moment M12 to act on the beams 22 and 23 of the second deforming portion 2 in the direction in which the rotational displacement of the second deforming portion 2 as a whole due to the bending moment M11 applied to the first deforming portion 1 is offset and setting the parameters such that the relative horizontal displacement distance ΔS1 during the rotational displacement of the second deforming portion 2 is the same as the horizontal displacement distance ΔS1′ of the tip 24 of the structure provided with no second deforming portion 2 as illustrated in FIGS. 2A′ to 2C′, the horizontal displacement distance of the vertical probe tip 24 can be strictly controlled at a level as low as 2 micrometers or less.

### Second Embodiment

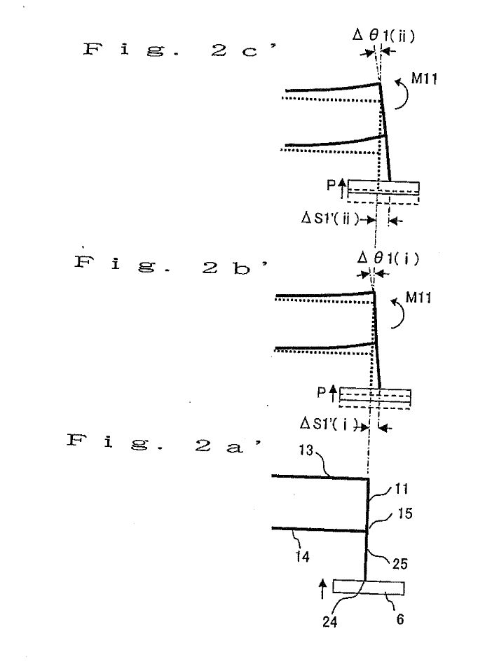

A second embodiment of the present invention will be described with reference to FIGS. 3A to 3D. In FIGS. 3A to 3D, a probe is illustrated in which a first deforming portion 1 is a related art cantilever and a second deforming portion 2 is connected substantially vertically in a −Z direction to an open end of the cantilever. FIGS. 3A to 3C illustrate a probe structure according to this embodiment of the present invention. The probe structure illustrated in FIGS. 3A′ to 3C′ has no second deforming portion at the same first deforming portion 1 but has a vertically extended portion 25 of the same vertical length as that of the second deforming portion 2. The following description will be given with the comparison of these structures.

In a related art cantilever structure, since bending deformation due to moment about an Y-axis of a horizontal beam is dominant with respect to load in a +Z direction accompanying overdrive, rotation accuracy Δθ2 of a vertical probe tip which is a contact portion increases as displacement in the Z direction increases. It is easily contemplated that this increase becomes significant as the vertical length of the second deforming portion 2 is greater or the length L33 of the horizontal beam 33 is smaller.

In FIGS. 3A to 3D, an operation of a first deforming portion will be described first. The horizontal beam 33 of the cantilever is kept in a substantially horizontal position until the pad 6 undergoes a relative vertical movement (in the +Z direction) and contacts the vertical probe tip 24 (FIGS. 3A and 3A′).

Then, when the pad 6 starts contacting the vertical probe tip 24 and overdrive is applied to push the vertical probe tip 24 upward in a certain fixed amount, the horizontal beam 33 of the cantilever undergoes rotational displacement by bending moment M21 in a −θy direction and a cantilever open end 31 undergoes rotational displacement by a very small angle Δθ1(i) (FIG. 3B). At this time, in FIG. 3B′, the vertically extended portion 25 undergoes rotational displacement together with the cantilever open end 31 and, as a result, the tip 24 undergoes horizontal displacement in a +X direction by ΔS2′(i), i.e., performs the scrubbing operation.

When the vertical probe tip 24 is pushed up to the maximum overdrive amount ODmax within the elastic limit of the horizontal beam 33, the horizontal beam 33 undergoes further rotational displacement and, as a result, the cantilever open end 31 undergoes rotational displacement by an angle of rotation Δθ2(ii) (FIG. 3C). At this time, in FIG. 3C′, the vertically extended portion 25 undergoes rotational displacement together with the cantilever open end 31 and, as a result, the tip 24 undergoes horizontal displacement by ΔS1′(ii) in the +X direction.

The amount of rotational displacement Δθ2 can be arbitrarily set in accordance with the length L33 of the horizontal beam, the beam width D33, the thickness of the material T and a spring constant k of the material in the cantilever as parameters.

An operation of the second deforming portion 2 will be described with reference to FIGS. 3A to 3D. The second deforming portion can be considered as a very small cantilever with the cantilever open end 31 as a fixed end and the horizontal beam portion 22 as a beam.

As illustrated in FIG. 3D, in a single operation with the end of the second deforming portion 2 as a fixing section, when the pad 6 starts contacting the vertical probe tip 24 and overdrive is applied, the beam sections 21, 22 and 23 undergo rotational displacement by bending moment M22 in a +θy direction. As a result, the vertical probe tip 24 is moved a very small distance ΔS2r in the horizontal direction. This horizontal distance ΔS2r is determined in accordance with the beam lengths L21, L22 and L23 and the beam widths D21, D22 and D23 as parameters.

Accompanying the rotational displacement of the horizontal beam 33 at the first deforming portion 1, the second deforming portion 2 has already undergone rotational displacement by an angle of rotation Δθ2. Accordingly, the second deforming portion 2 as a whole undergoes the rotational displacement Δθ2 and, at the same time, the vertical probe tip 24 undergoes horizontal displacement in a −x direction relatively as a very small cantilever. Here, in an actually used probing operation range, since Δθ2 is very small, a horizontal displacement distance ΔS2d in FIG. 3D can be considered to be substantially the same as the relative horizontal displacement distance ΔS2 of the rotational displacement the second deforming portion 2 undergoes in FIGS. 3B and 3C.

Accordingly, by causing the bending moment M22 to act on the beams 22 and 23 of the second deforming portion 2 in the direction in which the entire rotational displacement of the second deforming portion 2 due to the bending moment M21 applied to the first deforming portion 1 is offset and thereby setting the parameters such that the relative horizontal displacement distance ΔS2 during the rotational displacement of the second deforming portion 2 is the same as the horizontal displacement distance ΔS2′ of the tip 24 of the structure provided with no second deforming portion 2 as illustrated in FIGS. 3A′ to 3C′, the horizontal displacement distance of the vertical probe tip 24 can be strictly controlled at a level as low as 2 micrometers or less.

### Third Embodiment

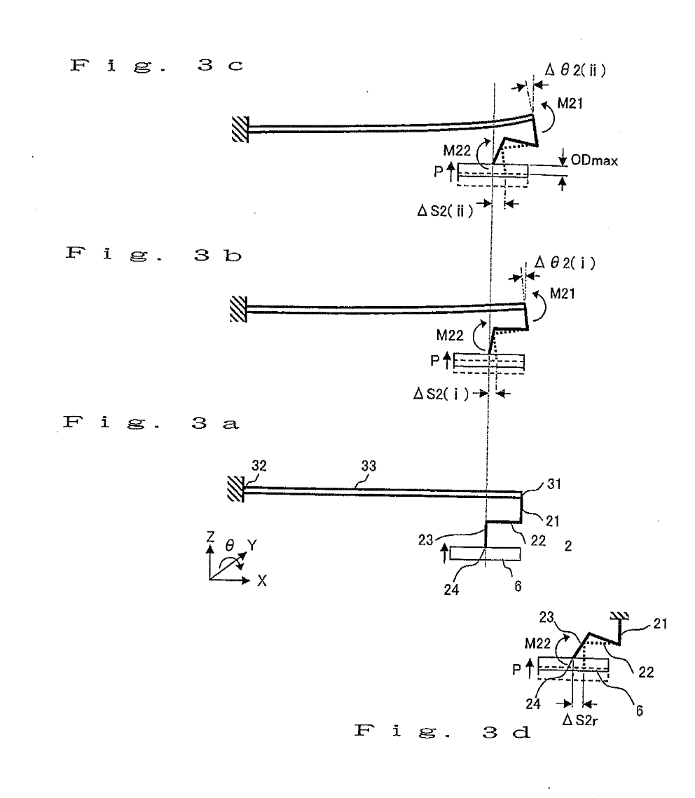

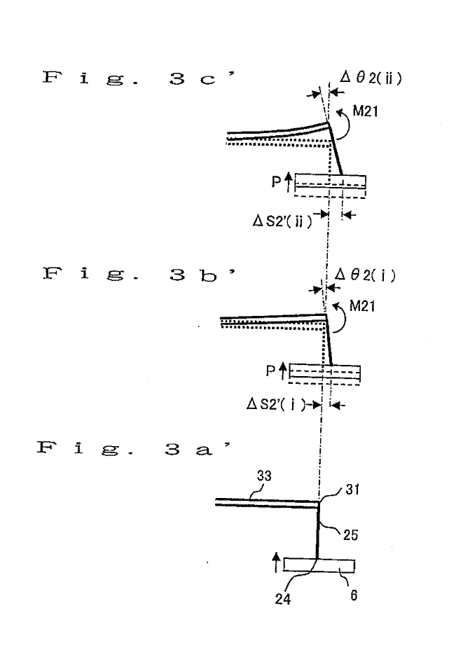

A third embodiment of the present invention will be described with reference to FIGS. 4A and 4B. FIG. 4A illustrates a vertical probe 41, a fixed end 42, horizontal beams 43 and 44, a probe tip 45 and a to-be-inspected electrode pad 6. The vertical probe 41, the fixed end 42 and the horizontal beams 43 and 44 constitute a parallel spring using a linkage mechanism as a principle. The present embodiment is an example in which a distance W between the horizontal beams 43 and 44 varies along horizontal direction.

The present embodiment is also an example in which an initial angle θh is set in the horizontal beam 43 in the parallelogram spring structure described in the first embodiment.

An operation of the present embodiment will be described in an example of FIG. 4A. The horizontal beams 43 and 44 of the probe are kept in substantially horizontal positions (illustrated by the solid line) until the pad 6 undergoes a relative vertical movement (in the +Z direction) and contacts the vertical probe tip 45. Then, when the pad 6 starts contacting the vertical probe tip 45 and overdrive is applied to push the vertical probe tip 45 upward in a certain fixed amount, the two horizontal beams 43 and 44 of the probe undergo individual rotational displacement and the vertical probe 41 is moves accordingly. The horizontal beams 43 and 44 are not parallel to each other and have an initial angle, their loci of rotational displacement differ from each other. Thus the vertical probe 41 illustrated by a dotted line is moved along a locus different from that with parallel horizontal beams 43 and 44.

Next, an operation of the third embodiment will be described with specific numerical values. The probe structure illustrated FIG. 4A is 1.3 mm in the horizontal full length, 0.07 mm in the width of the vertical probe 41, 0.03 mm in the widths of the horizontal beams 43 and 44 and 0.17 mm in the distance between the horizontal beams of the vertical probe 41. The probe structure is made of beryllium copper which is 0.02 mm in plate thickness. Other dimension values are as illustrated. An angle of the horizontal beam 44 to the horizontal direction is set to 0 degrees and an angle θh of the horizontal beam 43 to the horizontal direction is variable.

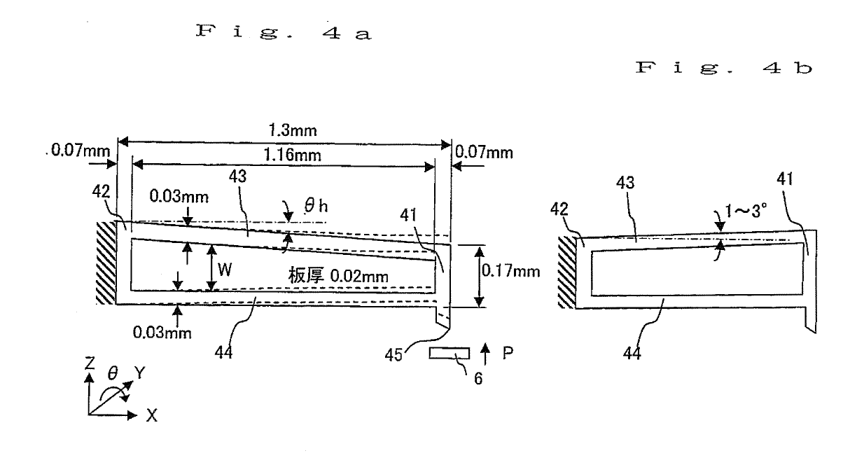

In the model described above, contact load P is applied to the probe tip 45 in the Z direction as illustrated in FIG. 4A and a scrubbing amount of the probe tip 45 with respect to a change in the angle θh to the horizontal direction of the horizontal beam 43 is calculated in a finite element method. The calculation result is illustrated in FIG. 5. As illustrated in FIG. 5, in value of θh, the scrubbing amount is about 0 near the angle of −2 degrees irrespective of the magnitude of the contact load P.

From the fact as described above, in a probe which includes a linkage mechanism formed by a vertically extending vertical probe and a pair of horizontal beams which extend in a direction crossing to the vertical direction and have a linear or curved configuration, one ends of the horizontal beams being connected to a fixed end and the other ends being connected to the vertical probe, and a distance between the pair of opposing horizontal beams varies continuously or discontinuously along a horizontal direction, it is apparent that the distance between the horizontal beams can be made being maximum at the fixed end and being minimum at the other ends near the vertical probe. Further, as illustrated in FIG. 4B, a probe in which initial angle (the angle at a moment before the probe acts) formed between a horizontal beam of the pair of horizontal beams disposed on a side of the tip of the vertical probe (on the side of electrode pad to-be-inspected) and horizontal line can be set to 0 degree. Further, it is apparent that the displacement amount of the linkage mechanism is calculated according to the formula of matrix analyzing method shown below, wherein the displacement of the tip of the vertical probe in the direction of X-axis among the displacement of the tip of the vertical probe in the matrix is nearly 0;

$$\begin{matrix}{p}_{1} = \vert \begin{matrix}{F}_{x 1} \\ {F}_{y 1} \\ {m}_{1}\end{matrix} \vert & {p}_{2} = \vert \begin{matrix}{F}_{x 2} \\ {F}_{y 2} \\ {m}_{2}\end{matrix} \vert \\ {d}_{1} = \vert \begin{matrix}{δ}_{x 1} \\ {δ}_{y 1} \\ {θ}_{1}\end{matrix} \vert & {d}_{2} = \vert \begin{matrix}{δ}_{x 2} \\ {δ}_{y 2} \\ {θ}_{2}\end{matrix} \vert\end{matrix} \} \\ \begin{matrix}{p}_{1} = {K}_{11} {d}_{1} + {K}_{12} {d}_{2} \\ {p}_{2} = {K}_{21} {d}_{1} + {K}_{22} {d}_{2}\end{matrix} \} \\ \begin{matrix}{K}_{11} = [ \begin{matrix}\frac{EA}{L} & 0 & 0 \\ 0 & \frac{12 EI}{{L}^{3}} & \frac{6 EI}{{L}^{2}} \\ 0 & \frac{6 EI}{{L}^{2}} & \frac{4 EI}{L}\end{matrix} ] & {K}_{12} = [ \begin{matrix}- \frac{EA}{L} & 0 & 0 \\ 0 & - \frac{12 EI}{{L}^{3}} & \frac{6 EI}{{L}^{2}} \\ 0 & - \frac{6 EI}{{L}^{2}} & \frac{2 EI}{L}\end{matrix} ] \\ {K}_{21} = [ \begin{matrix}- \frac{EA}{L} & 0 & 0 \\ 0 & - \frac{12 EI}{{L}^{3}} & - \frac{6 EI}{{L}^{2}} \\ 0 & \frac{6 EI}{{L}^{2}} & \frac{2 EI}{L}\end{matrix} ] & {K}_{22} = [ \begin{matrix}\frac{EA}{L} & 0 & 0 \\ 0 & \frac{12 EI}{{L}^{3}} & - \frac{6 EI}{{L}^{2}} \\ 0 & - \frac{6 EI}{{L}^{2}} & \frac{4 EI}{L}\end{matrix} ]\end{matrix} \}$$

wherein;
Fₓ: Load in the direction of X
F_{y}: Load in the direction of Y
δₓ: Displacement in the direction of X
δ_{y}: Displacement in the direction of Y
E: Young's modulus of the beam
I: Second section moment of the beam
A: Cross sectional of the beam
L: Length of the beam

### Fourth Embodiment

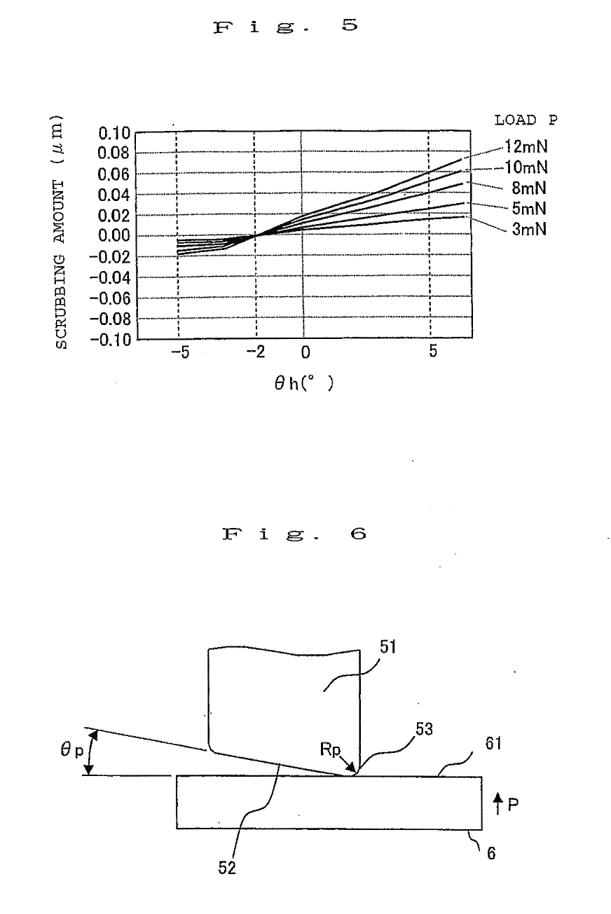

A fourth embodiment of the present invention will be described with reference to FIG. 6. In FIG. 6, a vertical probe tip 51, a vertical probe tip surface 52 and a vertical probe tip end 53 are illustrated. The vertical probe tip surface 52 is substantially a flat surface and, in this example, contacts an electrode pad at an angle of θp with a contact surface 61 of an electrode pad 6. The end 53 of the vertical probe tip surface which starts contacting the electrode pad 6 has a radius of curvature Rp.

Since the probe tip contacts the electrode pads as many as about 100,000 times in the inspection using a probe card, there is a possibility of wearing and deformation of the probe tip. However, as described in the first to third embodiments, the scrubbing operation can be eliminated as much as possible according to the probe structure of the present invention. Thus the vertical probe tip 51 and the electrode pad 6 always contact at the same contact position.

Accordingly, if the vertical probe tip surface 52 always keeps an angle of θp with the contact surface 61 of the electrode pad and if the radius of curvature Rp of the end 53 of the vertical probe tip surface which starts contacting the electrode pad 6 is minimized as much as possible, it is possible that the probe contact portion (i.e., the end 53) can contact the electrode pad always in a very small range even after the end 53 is worn out. Preferred specific numerical values are as follows; θp is about 8 degrees and the radius of curvature Rp is 2 micrometers or less, which have been given through experiments.

### Fifth Embodiment

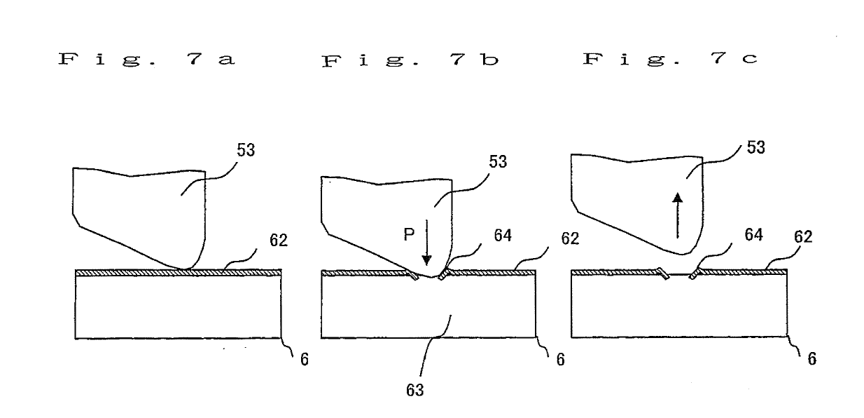

A fifth embodiment of the present invention will be described with reference to FIGS. 7A to 7C. In FIGS. 7A to 7C, a vertical probe tip 53, an oxide film 62 produced on a surface of an electrode pad 6 and an electrode pad material (e.g., aluminum) 63 are illustrated.

It has been described that it is possible to eliminate the scrubbing operation as much as possible and make only a very small portion of the probe tip be a contact portion with an electrode pad by the methods described in the first to fourth embodiments.

In FIGS. 7A to 7C, the oxide film (e.g., an aluminum oxide film) 62 of the electrode pad is typically formed as a thin film having the thickness of about 20 nm. The vertical probe tip 53 penetrates the oxide film 62 and the vertical probe tip 53 contacts the electrode pad material 63, whereby electrical conduction is established.

If large scrubbing is applied or excessively large load P is applied, the oxide film 62 separates from the pad 6 and adheres to the probe tip. This requires cleaning of the probe tip all the time. Thus, the load P must be a minimum required value.

An operation at this time will be described with reference to FIGS. 7A to 7C. FIG. 7A illustrates a state until the pad 6 undergoes a relative vertical movement (in a +Z direction) and contacts the vertical probe tip 53. Then, when the pad 6 starts contacting the vertical probe tip 53, overdrive is applied and the optimum maximum load Pmax is applied, the oxide film 62 of the pad surface is destroyed and the pad material 63 contacts the vertical probe tip 53, whereby electrical conduction is established as illustrated in FIG. 7B.

If the maximum load is optimum, the inspection can be completed without any adhesion of the destroyed oxide film 64 to the vertical probe tip 53 in a course in which the load P is released and the vertical probe tip 53 separates from the pad 6 at the completion of the inspection as illustrated in FIG. 7C. An optimum value of the load P is 20 mN or less and especially 10 mN to 20 mN, which has been given through experiments.

According to the probe of the present invention, a small deforming structure, which is a second deforming portion which has functions to correct horizontal displacement accompanying horizontal displacement or rotational displacement caused by a behavior of a first deforming portion, and strictly control the horizontal displacement, i.e., a scrubbing amount, at a level as low as 2 micrometers or less, is formed at a tip of the first deforming portion. With this probe, no removal of the electrode pad material occurs by a related art scrubbing operation for the LSIs that require no scrubbing operation, like the LCD driver LSIs. Further, since a proper scrubbing amount is provided for the electrode pad that requires a related art scrubbing operation, an oxide film on the surface of the electrode pad is penetrated without any removal of the oxide film to establish electrical conduction. Accordingly, no periodic cleaning is necessary and thus a probe card with reduced inspection cost can be provided.

Although preferred embodiments illustrated in the drawings have been described above, it is apparent to those skilled in the art that various changes and modifications can be easily made to the present invention without departing the scope of the invention. It is contemplated that the present invention includes such changes and modifications.

What is claimed is:

1. A probe comprising a first deforming portion which includes a linkage mechanism formed by a vertically extending vertical probe and a pair of horizontal beams which extend in a direction crossing to the vertical direction and have a linear or curved configuration, one ends of the horizontal beams being connected to a fixed end and the other ends being connected to the vertical probe, wherein:
a distance between the pair of opposing horizontal beams varies continuously or discontinuously along a horizontal direction; and
the distance between the horizontal beams is maximum at the fixed end and is minimum at the other ends near the vertical probe.

2. The probe according to claim 1, wherein initial angle (the angle at a moment before the probe acts) formed between a horizontal beam disposed on a side of the tip of the vertical probe (on the side of electrode pad) and horizontal line is set to 0 degree.

3. The probe according to claim 2, wherein the displacement amount of the linkage mechanism is calculated according to the formula of matrix analyzing method shown below, wherein the displacement of the tip of the vertical probe in the direction of X-axis among the displacement of the tip of the vertical probe in the matrix is nearly 0;
$$\begin{matrix}{p}_{1} = \vert \begin{matrix}{F}_{x 1} \\ {F}_{y 1} \\ {m}_{1}\end{matrix} \vert & {p}_{2} = \vert \begin{matrix}{F}_{x 2} \\ {F}_{y 2} \\ {m}_{2}\end{matrix} \vert \\ {d}_{1} = \vert \begin{matrix}{δ}_{x 1} \\ {δ}_{y 1} \\ {θ}_{1}\end{matrix} \vert & {d}_{2} = \vert \begin{matrix}{δ}_{x 2} \\ {δ}_{y 2} \\ {θ}_{2}\end{matrix} \vert\end{matrix} \} \\ \begin{matrix}{p}_{1} = {K}_{11} {d}_{1} + {K}_{12} {d}_{2} \\ {p}_{2} = {K}_{21} {d}_{1} + {K}_{22} {d}_{2}\end{matrix} \} \\ \begin{matrix}{K}_{11} = [ \begin{matrix}\frac{EA}{L} & 0 & 0 \\ 0 & \frac{12 EI}{{L}^{3}} & \frac{6 EI}{{L}^{2}} \\ 0 & \frac{6 EI}{{L}^{2}} & \frac{4 EI}{L}\end{matrix} ] & {K}_{12} = [ \begin{matrix}- \frac{EA}{L} & 0 & 0 \\ 0 & - \frac{12 EI}{{L}^{3}} & \frac{6 EI}{{L}^{2}} \\ 0 & - \frac{6 EI}{{L}^{2}} & \frac{2 EI}{L}\end{matrix} ] \\ {K}_{21} = [ \begin{matrix}- \frac{EA}{L} & 0 & 0 \\ 0 & - \frac{12 EI}{{L}^{3}} & - \frac{6 EI}{{L}^{2}} \\ 0 & \frac{6 EI}{{L}^{2}} & \frac{2 EI}{L}\end{matrix} ] & {K}_{22} = [ \begin{matrix}\frac{EA}{L} & 0 & 0 \\ 0 & \frac{12 EI}{{L}^{3}} & - \frac{6 EI}{{L}^{2}} \\ 0 & - \frac{6 EI}{{L}^{2}} & \frac{4 EI}{L}\end{matrix} ]\end{matrix} \}$$
wherein;
Fₓ: Load in the direction of X
F_{y}: Load in the direction of Y
δₓ: Displacement in the direction of X
δ_{y}: Displacement in the direction of Y
E: Young's modulus of the beam
I: Second section moment of the beam
A: Cross sectional of the beam
L: Length of the beam

4. The probe according to claim 1, wherein the tip of the vertical probe which contacts a to-be-inspected pad is substantially a flat surface and an angle of the flat surface of the tip to the horizontal direction (i.e., a direction of the plane of the to-be-inspected electrode pad) is in a range of 5 degrees to 10 degrees and a radius of curvature at the side of the acute angle in contact with the to-be-inspected pad is 2 micrometers or less.

5. The probe according to claim 1, wherein the horizontal displacement (scrubbing) of the tip of the vertical probe is 2 micrometers or less.
